(19) United States
(12) Patent Application Publication
(10) Pub. No.: US 2025/0165658 A1
(43) Pub. Date: May 22, 2025

(54) ITERATIVE GUIDED ARCHITECTURE DESIGN BASED ON SELF-OPTIMIZING ANALYTICAL MODELS

(71) Applicant: Samsung Electronics Co., Ltd., Suwon-si (KR)

(72) Inventors: Nichols Anthony ROMERO, Naperville, IL (US); Robert William WISNIEWSKI, Ossining, NY (US); Aditya Madhusudan DESHPANDE, Sunnyvale, CA (US); Manisha GAJBE, Folsom, CA (US); Arun Francis RODRIGUES, Albuquerque, NM (US); Matthew Douglas TURNER, Missoula, MT (US)

(21) Appl. No.: 18/638,647

(22) Filed: Apr. 17, 2024

Related U.S. Application Data
(60) Provisional application No. 63/600,009, filed on Nov. 16, 2023.

(51) Int. Cl. G06F 30/13

(52) U.S. Cl. CPC G06F 30/13

(57) ABSTRACT

Provided are systems, methods, and apparatuses for iterative guided architecture design based on self-optimizing analytical models. In one or more examples, the systems, devices, and methods include determining a figure of merit (FOM) of a reference architecture based on executing a workload on the reference architecture and measuring a hardware event associated with executing the workload. In some examples, the systems, devices, and methods include determining an analytical model based on the FOM and based on performing roofline analysis on the reference architecture. In some examples, the systems, devices, and methods include estimating performance of the workload on the target architecture based on the analytical model identifying an optimal design based on validating the analytical model on a plurality of architectures executing the workload.

### CROSS-REFERENCE TO RELATED APPLICATIONS

This application claims the benefit of U.S. Provisional Patent Application Ser. No. 63/600,009 Nov. 16 2023, which is incorporated by reference herein for all purposes.

### TECHNICAL FIELD

The disclosure relates generally to system architecture design, and more particularly to iterative guided architecture design based on self-optimizing analytical models.

### BACKGROUND

The present background section is intended to provide context only, and the disclosure of any concept in this section does not constitute an admission that said concept is prior art.

System architecture design can include the process of defining a system's components, interfaces, data, and modules to meet specific requirements. System architecture design can be part of software engineering, serving as a blueprint for the project and the system. System architecture design can define the interactions between the hardware and software systems, as well as the work assignments for design teams. System architecture design can also define how the system works, how it meets functional and non-functional requirements, and how it adapts to feedback and changes. System architecture can include system components and the sub-systems that are developed, which work together to implement the overall system. System design can be scaled based on the load experienced by the system, where machines can be replicated when the load increases, and machines can be removed when the load decreases.

The above information disclosed in this Background section is only for enhancement of understanding of the background of the disclosure and therefore it may contain information that does not constitute prior art.

### SUMMARY

In various embodiments, the systems and methods described herein include systems, methods, and apparatuses for iterative guided architecture design based on self-optimizing analytical models. In some aspects, the techniques described herein relate to a method of optimizing an architecture design, the method including: determining a figure of merit (FOM) of a reference architecture based on executing a workload on the reference architecture and measuring a hardware event associated with executing the workload, the hardware event including a performance metric associated with at least one of a processor of the reference architecture, a memory of the reference architecture, or a storage device of the reference architecture; determining an analytical model based on the FOM and based on performing roofline analysis on the reference architecture; estimating performance of the workload on a target architecture based on the analytical model; and identifying an optimal design of the target architecture based on validating the analytical model on a plurality of architectures executing the workload.

In some aspects, the techniques described herein relate to a method, further including identifying an outlier based on validating the analytical model, wherein validating the analytical model is based on the plurality of architectures executing the workload and comparing at least one hardware event of the plurality of architectures to the hardware event of the reference architecture.

In some aspects, the techniques described herein relate to a method, further including: determining a root cause of the outlier that is identified based on validating the analytical model on the plurality of architectures, wherein the root cause of the outlier is determined based on at least one of: analyzing a list of parameters and determining a parameter from the list of parameters is not represented in the analytical model, comparing a configuration setting of the reference hardware to at least one of a corresponding configuration setting of the target configuration or a corresponding configuration setting of at least one architecture of the plurality of architectures, and identifying a configuration setting of the reference hardware not represented in the analytical model based on the comparing; and modifying the analytical model based on the outlier, wherein modifying the analytical model includes at least one of: adjusting a parameter of the analytical model, adding a parameter to the analytical model, removing a parameter of the analytical model, adjusting a scalar value of the analytical model.

In some aspects, the techniques described herein relate to a method, further including determining the outlier is resolved based on validating the modified analytical model on the plurality of architectures, wherein the modified analytical model.

In some aspects, the techniques described herein relate to a method, further including identifying a design point deficiency in the target architecture based on estimating performance of the workload on the target architecture using the modified analytical model.

In some aspects, the techniques described herein relate to a method, further including modifying the target architecture based on modifying a design point of the target architecture to resolve the design point deficiency.

In some aspects, the techniques described herein relate to a method, wherein identifying the optimal design is based on estimating performance of the workload on the modified target architecture using the modified analytical model.

In some aspects, the techniques described herein relate to a method, further including wherein the FOM includes at least a wall-clock time associated with the workload executing on the reference architecture.

In some aspects, the techniques described herein relate to a method, wherein: the plurality of architectures includes a first virtual machine and a second virtual machine, a first configuration setting of an architecture of the first virtual machine diverges from a corresponding configuration setting of the reference architecture and the second virtual machine, and a second configuration setting of an architecture of the second virtual machine diverges from a corresponding configuration setting of the reference architecture and the first virtual machine.

In some aspects, the techniques described herein relate to a method, wherein: the reference architecture includes a system-on-chip (SoC) architecture, the first virtual machine includes a first virtual SoC architecture, and the second virtual machine includes a second virtual SoC architecture.

In some aspects, the techniques described herein relate to a device, including: at least one memory; and at least one processor coupled with the at least one memory configured to: determine a figure of merit (FOM) of a reference architecture based on executing a workload on the reference architecture and measuring a hardware event associated with executing the workload, the hardware event including a performance metric associated with at least one of a processor of the reference architecture, a memory of the reference architecture, or a storage device of the reference architecture; determine an analytical model based on the FOM and based on performing roofline analysis on the reference architecture; estimate performance of the workload on a target architecture based on the analytical model; and identify an optimal design of the target architecture based on validating the analytical model on a plurality of architectures executing the workload.

In some aspects, the techniques described herein relate to a device, wherein the at least one processor is configured to identify an outlier based on validating the analytical model, wherein validating the analytical model is based on the plurality of architectures executing the workload and comparing at least one hardware event of the plurality of architectures to the hardware event of the reference architecture.

In some aspects, the techniques described herein relate to a device, wherein the at least one processor is configured to: determine a root cause of the outlier that is identified based on validating the analytical model on the plurality of architectures, wherein the root cause of the outlier is determined based on at least one of: analyzing a list of parameters and determining a parameter from the list of parameters is not represented in the analytical model, comparing a configuration setting of the reference hardware to at least one of a corresponding configuration setting of the target configuration or a corresponding configuration setting of at least one architecture of the plurality of architectures, and identifying a configuration setting of the reference hardware not represented in the analytical model based on the comparing; and modify the analytical model based on the outlier.

In some aspects, the techniques described herein relate to a device, wherein the at least one processor is configured to determine the outlier is resolved based on validating the modified analytical model on the plurality of architectures.

In some aspects, the techniques described herein relate to a device, wherein the at least one processor is configured to identify a design point deficiency in the target architecture based on estimating performance of the workload on the target architecture using the modified analytical model.

In some aspects, the techniques described herein relate to a device, wherein the at least one processor is configured to modify the target architecture based on modifying a design point of the target architecture to resolve the design point deficiency.

In some aspects, the techniques described herein relate to a device, wherein identifying the optimal design is based on estimating performance of the workload on the modified target architecture using the modified analytical model.

In some aspects, the techniques described herein relate to a non-transitory computer-readable medium storing code that includes instructions executable by a processor of a device to: determine a figure of merit (FOM) of a reference architecture based on executing a workload on the reference architecture and measuring a hardware event associated with executing the workload, the hardware event including a performance metric associated with at least one of a processor of the reference architecture, a memory of the reference architecture, or a storage device of the reference architecture; determine an analytical model based on the FOM and based on performing roofline analysis on the reference architecture; estimate performance of the workload on a target architecture based on the analytical model; and identify an optimal design of the target architecture based on validating the analytical model on a plurality of architectures executing the workload.

In some aspects, the techniques described herein relate to a non-transitory computer-readable medium, wherein the code includes further instructions executable by the processor to cause the device to identify an outlier based on validating the analytical model, wherein validating the analytical model is based on the plurality of architectures executing the workload and comparing at least one hardware event of the plurality of architectures to the hardware event of the reference architecture.

In some aspects, the techniques described herein relate to a non-transitory computer-readable medium, wherein the code includes further instructions executable by the processor to cause the device to: determine a root cause of the outlier that is identified based on validating the analytical model on the plurality of architectures, wherein the root cause of the outlier is determined based on at least one of: analyzing a list of parameters and determining a parameter from the list of parameters is not represented in the analytical model, comparing a configuration setting of the reference hardware to at least one of a corresponding configuration setting of the target configuration or a corresponding configuration setting of at least one architecture of the plurality of architectures, and identifying a configuration setting of the reference hardware not represented in the analytical model based on the comparing; and modify the analytical model based on the outlier.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The techniques described herein for iterative guided architecture design based on self-optimizing analytical models provide multiple advantages and benefits. For example, the techniques provide identification of key hardware features in the early stages of the architecture design process, saving design time. Additionally, the techniques provide identification of key hardware features before the use of resource intensive techniques such as simulators, increasing the efficiency of the design process. Additionally, the techniques include a high-fidelity analytical model that provides a more efficient unbiased architecture design process, resulting in increased performance and power efficiency in architecture designs.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings wherein:

FIG. 1 illustrates an example system in accordance with one or more implementations as described herein.

FIG. 2 illustrates details of the system of FIG. 1, according to one or more implementations as described herein.

FIG. 3 illustrates an example design process in accordance with one or more implementations as described herein.

FIG. 4 illustrates an example design process in accordance with one or more implementations as described herein.

FIG. 5 depicts a flow diagram illustrating an example method associated with the disclosed systems, in accordance with example implementations described herein.

FIG. 6 depicts a flow diagram illustrating an example method associated with the disclosed systems, in accordance with example implementations described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used as examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

The following description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Any data processing may include data buffering, aligning incoming data from multiple communication lanes, forward error correction (“FEC”), and/or others. For example, data may be first received by an analog front end (AFE), which prepares the incoming for digital processing (e.g., via digital signal processors (DSPs)). The digital portion of the transceivers may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, system-on-a-chip, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

Architecture designing includes the challenge of optimizing key hardware features for a set of workloads. Workloads may be characterized by various performance analysis techniques. The outcomes from using these techniques are then used to optimize key hardware features. In some cases, key hardware limiters for a given workload may be unknown a priori and/or unknown a posteriori.

Conventional approaches to architecture design have been achieved by optimizing key hardware features to achieve optimal performance on standard benchmarks (e.g., General Matrix Multiplication (GEMM) benchmark, STREAM benchmark, etc.). In this way, architecture design may be achieved by a relatively laborious process of adjusting key hardware features and analyzing outcomes from simulator or early hardware until a figure of merit is deemed satisfactory (e.g., good enough, suitable).

A figure of merit (FOM) can be a performance metric that measures the performance of a device, system, and/or method compared to alternatives. In some examples, the FOM can indicate the performance of a workload on hardware that is being architected. FOMs can be a numerical quantity based on one or more characteristics of a system or device that represents a measure of efficiency or effectiveness. FOMs can be represented as a point along a scale. In some cases, FOMs may compare the merits of a device or system with other devices/systems. Examples of FOM can include clock rate of a processing unit, floating point operations per second (FLOPS) of a processing unit, bandwidth of memory, throughput of memory, memory latency (e.g., number of clock cycles it takes for a memory module to access data and make the data available on its output pins), and the like. Thus, FOM can be a numerical expression representing the performance or efficiency of a given device, component of a device, process, etc.

Identifying key hardware limiters in the performance modeling process can be relatively difficult as the models themselves may be biased by the reference architecture, where the reference architecture may have different properties (e.g., design characteristics, configuration settings) from the target architecture. For example, a reference architecture may include a first set of configuration settings for one or more physical components and/or virtual components (e.g., logical components), while the target architecture may include a second set of configuration settings for one or more physical components and/or virtual components of the target architecture, where at least one setting of a physical component and/or virtual component of the reference architecture varies from at least one setting of a physical component and/or virtual component of the target architecture. Example configuration settings may include at least one of a processor setting (e.g., clock speed, FLOPS), a memory setting (e.g., memory size, memory latency, memory bandwidth), a storage setting (e.g., write speed, read speed, storage type such as SSD or disk drive), a cache setting (e.g., cache size, cache bandwidth), a network setting (e.g., network bandwidth), etc. In some cases, optimization of key hardware features that impact FOMs can be deferred to later stages in the design process, but deferring optimization can be more expensive in terms of resources (e.g., advanced simulators, human input, etc.).

The roofline model is a visual performance model that estimates the performance of a workload running on a given system (e.g., multi-core, many-core, or accelerator processor architecture). The roofline model shows the hardware limitations, and the potential benefit and priority of optimizations. The roofline model can show the fundamental performance imposed by hardware and the potential benefits that can be achieved by optimizations. The roofline model may be used as a log-log plot of arithmetic intensity vs floating point operations per second (FLOPS). The roofline may be a line whose slope is associated with memory bandwidth effects and a flat portion of the line may be associated with peak flop rate. A roofline model can be used to identify performance limiters, motivate software optimizations, determine when to stop optimizing, and/or predict performance on future machines or architectures.

The techniques described herein include design logic to provide iterative guided architecture design based on self-optimizing analytical models. The roofline model can include a visual model that assesses the performance of a workload against the hardware the workload is running on. Roofline models can indicate the compute-memory ratio of a computation. In some cases, roofline models can be represented as a two-dimensional plot with performance on a first axis (e.g., y-axis) and arithmetic or computational intensity on a second axis (e.g., x-axis). In some examples, the roofline is plotted as a line that starts at an initial point on the graph (e.g., x=0, y=0). In some cases, the roofline may include a sloped portion and a flat portion. For example, the roofline may move linearly from the initial point in an upward slope that is similar to the slope of plotting y=x (e.g., y=x, y=2*x, y=0.5*x, etc.). In some cases, the plot of the roofline may reach a peak level in relation to the y-axis (e.g., a peak performance level, peak FLOPs). At this point, the roofline may flatten (e.g., little to no change in performance (y) as FLOPs (x) grows, following the sloped portion of the roofline). In some cases, a goal for optimizing key hardware features of a system for a given workload (e.g., application, compute kernel, etc.) may include keeping the performance of a given system as close to the roofline as possible. When application code of a workload runs below the sloped portion of the roofline, the workload is said to be memory bound. When application code of the workload runs below the flat portion of the roofline, the workload is said to be FLOPS bound, where the application code of the workload can be a measure of what can improve the application code.

Accordingly, the roofline model can include a visual performance model that provides performance estimates of a given compute kernel or application running on a given system (e.g., multi-core, many-core, or accelerator processor architectures). Roofline models can show inherent hardware limitations, potential benefit, and/or priority of optimizations. By combining locality, bandwidth, and different parallelization paradigms into a single performance figure, some roofline models can assess the quality of attained performance instead of using simple percent-of-peak estimates, as roofline models provide insights on both the implementation and inherent performance limitations.

In some cases, roofline analysis indicates how close an application is to respective hardware limits. Roofline analysis may refer to floating point operations per second (FLOPS) that are a measure of performance of applications that are using floating-point calculations. Arithmetic intensity is a ratio between work done (FLOPS) and memory traffic (bytes) and measured in FLOPS/byte. Roofline analysis can include visual models that assess the performance of an application in relation to the underlying hardware. To characterize an workload on a roofline, one or more pieces of information may be collected about the workload. The pieces of information may include at least one of run time, number of FLOPs performed (e.g., total number of FLOPs performed), and/or the number of bytes moved (e.g., total number of bytes read and/or written). Roofline analysis can apply to an entire workload or for only a code region that is of interest.

In some cases, the systems and methods are based on one or more hardware events (e.g., a minimum number of hardware events). In some examples, the systems and methods are based on collected hardware events for the workload on the reference architecture. In some cases, the hardware event may include a performance metric associated with at least one of a processor of the reference architecture, a memory of the reference architecture, or a storage device of the reference architecture based on the reference architecture executing the workload. For example, the one or more hardware events may include at least one of: (a) a total number of floating point operations; (b) a total volume of data movement between main memory and the last level of cache; and/or (c) a total hit rates on the last level of cache (LLC).

Last level cache (LLC) can be the highest-numbered cache that a processor accesses before fetching from main memory. LLC can be the last chance for memory accesses to avoid the expensive latency of the processor having to go to main memory. LLC can be shared by all the cores of a multi-core system. LLC can be referred to as a system cache. LLC can reduce the number of accesses to off-chip memory. LLC can reduce system latency and power consumption while increasing achievable bandwidth. LLC can be located before a memory controller for off-chip dynamic random-access memory (DRAM) or flash memory. LLC can be on-chip, which is faster than off-chip memory. LLC can have a wider, faster connection to a CPU cluster than DRAM.

In some cases, the systems and methods described herein may be incorporated in a system on a chip (SoC). For example, the design architecture may include the design architecture of an SoC (e.g., one or more components of an SoC). SoCs can include a microchip configured with all the necessary electronic circuits for a system to function on a single integrated circuit (IC). SoCs are different from traditional devices and computer architectures, where a separate chip is used for each of the central processing unit (CPU), graphics processing unit (GPU), RAM, and other functional components. SoCs simplify circuit board design by eliminating separate and large system components, resulting in improved power and speed without compromising system functionality. SoCs can also offer more advanced functionality and computing power than microcontrollers. In some examples, the systems and methods described herein apply to the design architecture of SoCs.

In some examples, a virtual machine (VM) can be the virtualization or emulation of a computer system. Virtual machines can be based on computer architectures and provide the functionality of a physical computer. VM implementations may involve specialized hardware, software, or a combination of the two. In some cases, VMs can differ and can be organized by their function. A VM can include a software-based computer that acts like a physical computer. VMs can be referred to as guest machines. VMs can be created by borrowing resources from a physical host computer or a remote server.

In some cases, the max function returns the value in a sequence that is greater than any other value in the input sequence. From a given set of numeric values (e.g., sequence of numbers), the max function may return the highest number. The formula for the max function may be constructed as follows: MAX (number1, number2, . . . ).

The design logic includes any combination of hardware, logical circuitry, firmware, and/or software to provide iterative guided architecture design based on self-optimizing analytical models. An analytical model derived from a roofline analysis (e.g., using hardware events) based on a reference architecture may be used in architecture design. The analytical models described herein may include an analytical model (e.g., analytical roofline model), a hardware-counter-based analytical model, a resource-based analytical model, or any combination thereof. Equations 1 and 2, included herein, can be examples of analytical models. The design logic may be configured to run workloads on multiple divergent architectures to obtain an FOM and compare the obtained FOM against an FOM predicted by the analytical model. The design logic may be configured to identify outliers from the analysis and use the identified outliers to improve the analytical model (e.g., the analytical model based on the reference architecture). Using the identified outliers to improve the analytical model provides several benefits. For example, improving the analytical model based on the identified outliers provides identification of key hardware features in the early stages of the architecture design process (e.g., before the use of resource intensive techniques such as simulators). And identifying key hardware features in the early stages of the architecture design process minimizes the expense associated with deferring optimization (e.g., in terms of resources). Also, improving the analytical model based on the identified outliers provides a high-fidelity analytical model. Thus, the techniques described herein provide a more efficient unbiased architecture design process.

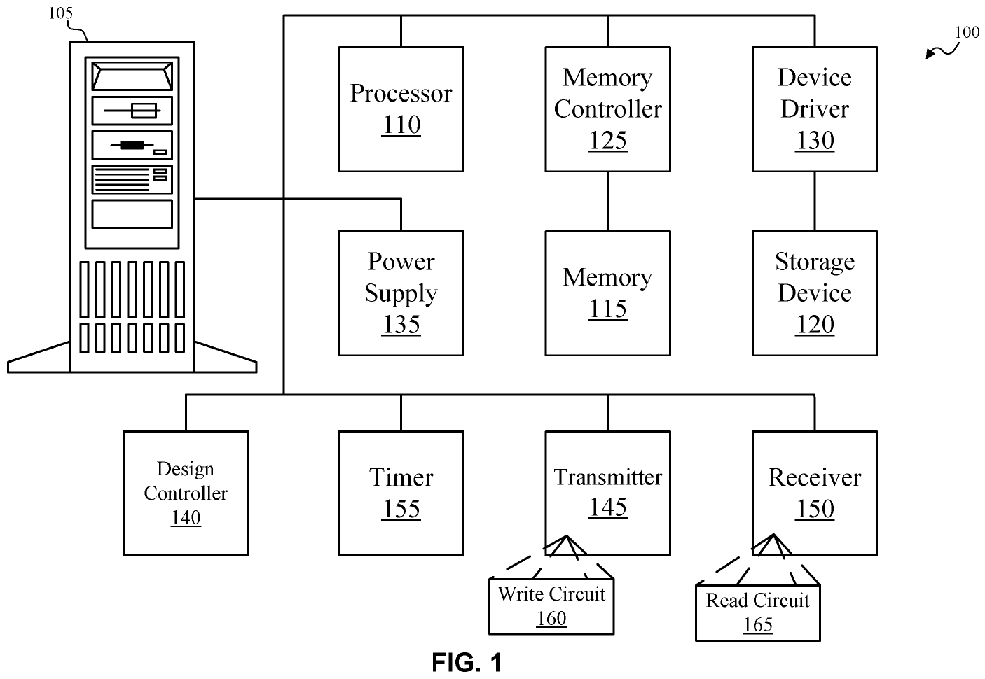

FIG. 1 illustrates an example system 100 in accordance with one or more implementations as described herein. In FIG. 1, machine 105, which may be termed a host, a system, or a server, is shown. While FIG. 1 depicts machine 105 as a tower computer, embodiments of the disclosure may extend to any form factor or type of machine. For example, machine 105 may be a rack server, a blade server, a desktop computer, a tower computer, a mini tower computer, a desktop server, a laptop computer, a notebook computer, a tablet computer, etc. In some examples, system 100 (e.g., machine 105) depicts one or more aspects (e.g., components, configuration settings) of a representative architecture, of a target architecture, and/or of one or more architectures (e.g., one or more architectures for validation of an analytical model).

Machine 105 may include processor 110, memory 115, and storage device 120. Processor 110 may be any variety of processor. It is noted that processor 110, along with the other components discussed below, are shown outside the machine for ease of illustration: embodiments of the disclosure may include these components within the machine. While FIG. 1 shows a single processor 110, machine 105 may include any number of processors, each of which may be single core or multi-core processors, each of which may implement a Reduced Instruction Set Computer (RISC) architecture or a Complex Instruction Set Computer (CISC) architecture (among other possibilities), and may be mixed in any desired combination.

Processor 110 may be coupled to memory 115. Memory 115 may be any variety of memory, such as flash memory, Dynamic Random Access Memory (DRAM), Static Random Access Memory (SRAM), Persistent Random Access Memory, Ferroelectric Random Access Memory (FRAM), or Non-Volatile Random Access Memory (NVRAM), such as Magnetoresistive Random Access Memory (MRAM), Phase Change Memory (PCM), or Resistive Random-Access Memory (ReRAM). Memory 115 may include volatile and/or non-volatile memory. Memory 115 may use any desired form factor: for example, Single In-Line Memory Module (SIMM), Dual In-Line Memory Module (DIMM), Non-Volatile DIMM (NVDIMM), etc. Memory 115 may be any desired combination of different memory types, and may be managed by memory controller 125. Memory 115 may be used to store data that may be termed “short-term”: that is, data not expected to be stored for extended periods of time. Examples of short-term data may include temporary files, data being used locally by applications (which may have been copied from other storage locations), and the like.

Processor 110 and memory 115 may support an operating system under which various applications may be running. These applications may issue requests (which may be termed commands) to read data from or write data to either memory 115 or storage device 120. When storage device 120 is used to support applications reading or writing data via some sort of file system, storage device 120 may be accessed using device driver 130. While FIG. 1 shows one storage device 120, there may be any number (one or more) of storage devices in machine 105. Storage device 120 may support any desired protocol or protocols, including, for example, the Non-Volatile Memory Express (NVMe) protocol, a Serial Attached Small Computer System Interface (SCSI) (SAS) protocol, or a Serial AT Attachment (SATA) protocol. Storage device 120 may include any desired interface, including, for example, a Peripheral Component Interconnect Express (PCIe) interface, or a Compute Express Link (CXL) interface. Storage device 120 may take any desired form factor, including, for example, a U.2 form factor, a U.3 form factor, a M.2 form factor, Enterprise and Data Center Standard Form Factor (EDSFF) (including all of its varieties, such as E1 short, E1 long, and the E3 varieties), or an Add-In Card (AIC).

While FIG. 1 uses the term “storage device,” embodiments of the disclosure may include any storage device formats that may benefit from the use of computational storage units, examples of which may include hard disk drives, Solid State Drives (SSDs), or persistent memory devices, such as PCM, ReRAM, or MRAM. Any reference to “storage device” “SSD” below should be understood to include such other embodiments of the disclosure and other varieties of storage devices. In some cases, the term “storage unit” may encompass storage device 120 and memory 115.

Machine 105 may include power supply 135. Power supply 135 may provide power to machine 105 and its components. Power supply 135 may have a maximum amount of power that may be used (before exceeding the specifications of power supply 135): this information may be known to machine 105 and may be used, for example, by design controller 140 in determining the efficiency of an analytical model (e.g., performance model). Operating levels of power supply 135 may be adjusted based on the systems and methods described herein (e.g., increase voltage, decrease voltage, increase current, decrease current, etc.).

Machine 105 may include transmitter 145 and receiver 150. Transmitter 145 or receiver 150 may be respectively used to transmit or receive data. In some cases, transmitter 145 and/or receiver 150 may be used to communicate with processor 110, memory 115, and/or storage device 120. Transmitter 145 may include write circuit 160, which may be used to write data into storage, such as a register, in memory 115 and/or storage device 120. In a similar manner, receiver 150 may include read circuit 165, which may be used to read data from storage, such as a register, from memory 115 and/or storage device 120. In the illustrated example, machine 105 may include timer 155. Timer 155 may be used to time operations, floating point operations per second, data transfers, data write latencies, data read latencies, and the like.

In one or more examples, machine 105 may be implemented with any type of apparatus. Machine 105 may be configured as (e.g., as a host of) one or more of a server such as a compute server, a storage server, storage node, a network server, a supercomputer, data center system, and/or the like, or any combination thereof. Additionally, or alternatively, machine 105 may be configured as (e.g., as a host of) one or more of a computer such as a workstation, a personal computer, a tablet, a smartphone, and/or the like, or any combination thereof. Machine 105 may be implemented with any type of apparatus that may be configured as a device including, for example, an accelerator device, a storage device, a network device, a memory expansion and/or buffer device, a central processing unit (CPU), a graphics processing unit (GPU), a neural processing unit (NPU), a tensor processing unit (TPU), and/or the like, or any combination thereof.

Any communication between devices including machine 105 (e.g., host, computational storage device, and/or any intermediary device) can occur over an interface that may be implemented with any type of wired and/or wireless communication medium, interface, protocol, and/or the like including PCIe, NVMe, Ethernet, NVMe-oF, Compute Express Link (CXL), and/or a coherent protocol such as CXL.mem, CXL.cache, CXL.IO and/or the like, Gen-Z, Open Coherent Accelerator Processor Interface (OpenCAPI), Cache Coherent Interconnect for Accelerators (CCIX), Advanced extensible Interface (AXI) and/or the like, or any combination thereof, Transmission Control Protocol/Internet Protocol (TCP/IP), FibreChannel, InfiniBand, Serial AT Attachment (SATA), Small Computer Systems Interface (SCSI), Serial Attached SCSI (SAS), iWARP, any generation of wireless network including 2G, 3G, 4G, 5G, and/or the like, any generation of Wi-Fi, Bluetooth, near-field communication (NFC), and/or the like, or any combination thereof. In some embodiments, the communication interfaces may include a communication fabric including one or more links, buses, switches, hubs, nodes, routers, translators, repeaters, and/or the like. In some embodiments, system 100 may include one or more additional apparatus having one or more additional communication interfaces.

Any of the functionality described herein, including any of the host functionality, device functionally, design controller 140 functionality, and/or the like, may be implemented with hardware, software, firmware, or any combination thereof including, for example, hardware and/or software combinational logic, sequential logic, timers, counters, registers, state machines, volatile memories such as dynamic random access memory (DRAM) and/or static random access memory (SRAM), nonvolatile memory including flash memory, persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application specific integrated circuits (ASICs) CPUs including complex instruction set computer (CISC) processors such as x86 processors and/or reduced instruction set computer (RISC) processors such as RISC-V and/or ARM processors), graphics processing units (GPUs), neural processing units (NPUs), tensor processing units (TPUs) and/or the like, executing instructions stored in any type of memory. In some embodiments, one or more components of design controller 140 may be implemented as a system-on-chip (SOC).

In some examples, design controller 140 may include any one or combination of logic (e.g., logical circuit), hardware (e.g., processing unit, memory, storage), software, firmware, and the like. In some cases, design controller 140 may perform one or more functions in conjunction with processor 110. In some cases, at least a portion of design controller 140 may be implemented in or by processor 110 and/or memory 115. The one or more logic circuits of design controller 140 may include any one or combination of multiplexers, registers, logic gates, arithmetic logic units (ALUs), cache, computer memory, microprocessors, processing units (CPUs, GPUs, NPUs, and/or TPUs), FPGAs, ASICs, etc., that enable design controller 140 to provide iterative guided architecture design based on self-optimizing analytical models.

In one or more examples, design controller 140 may be configured to provide iterative guided architecture design based on self-optimizing analytical models. In some cases, design controller 140 may improve analytical model robustness by exploring a divergent architectures space (e.g., that is orthogonal to reference architectures). In some aspects, design controller 140 may leverage hardware events collected via virtualization on multiple architectures, analytical models derived from roofline analysis, outlier statistics, and/or optimization algorithms. In some cases, design controller 140 provides identification of key hardware features in the early stages of the architecture design process, saving design time. In some examples, design controller 140 may provide identification of key hardware features before the use of resource intensive techniques such as simulators, increasing the efficiency of the design process. In some cases, design controller 140 may generate a high-fidelity analytical model that provides a more efficient unbiased architecture design process, resulting in increased performance and power efficiency in architecture designs.

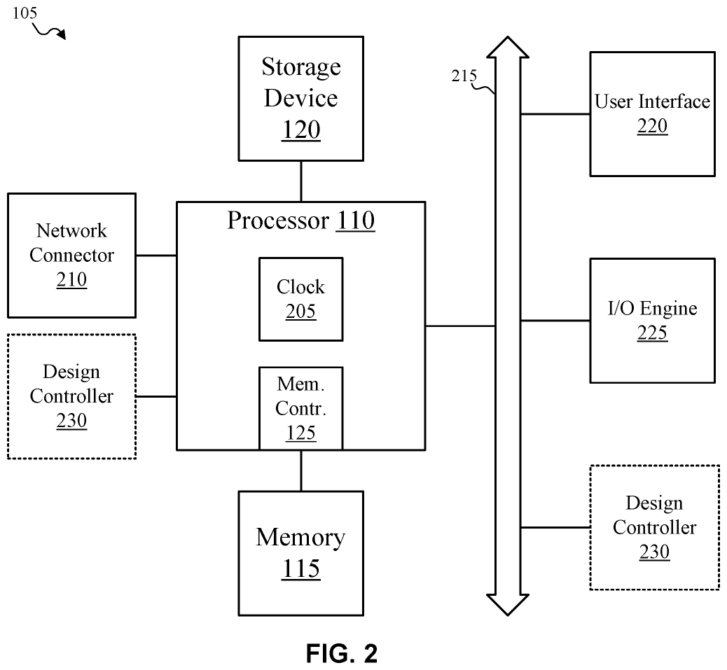

FIG. 2 illustrates details of machine 105 of FIG. 1, according to examples described herein. In the illustrated example, machine 105 may include one or more processors 110, which may include memory controllers 125 and clocks 205, which may be used to coordinate the operations of the components of the machine. Processors 110 may be coupled to memories 115, which may include random access memory (RAM), read-only memory (ROM), or other state preserving media, as examples. Processors 110 may be coupled to storage devices 120, and to network connector 210, which may be, for example, an Ethernet connector or a wireless connector. Processors 110 may be connected to buses 215, to which may be attached user interfaces 220 and Input/Output (I/O) interface ports that may be managed using I/O engines 225, among other components. As shown, processors 110 may be coupled to design controller 230, which may be an example of design controller 140 of FIG. 1. Additionally, or alternatively, processors 110 may be connected to buses 215, to which may be attached design controller 230.

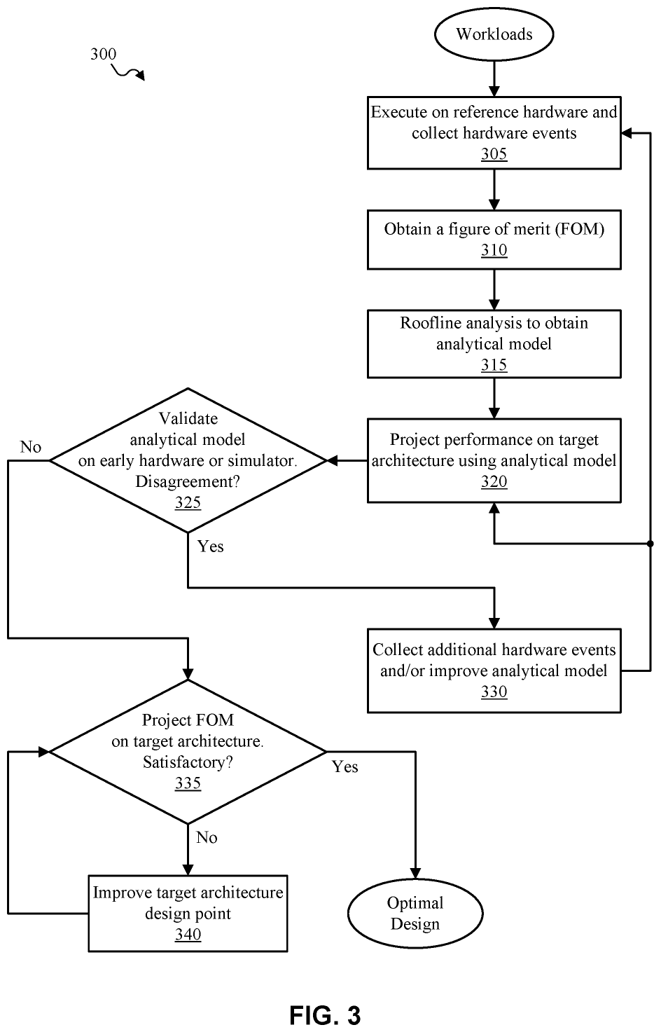

FIG. 3 illustrates an example process 300 in accordance with one or more implementations as described herein. Process 300 illustrates an example process for iterative guided architecture design based on self-optimizing analytical models. In some configurations, process 300 may be implemented by design controller 140 of FIG. 1 and/or design controller 230 of FIG. 2. In some configurations, process 300 may be implemented in conjunction with machine 105, components of machine 105, or any combination thereof. The depicted process 300 is just one implementation and one or more operations of process 300 may be rearranged, reordered, omitted, and/or otherwise modified such that other implementations are possible and contemplated.

In some examples, process 300 may initiate based on a workload (e.g., one or more workloads). In some cases, a workload that is FLOPS bound and/or memory bandwidth bound may be selected for process 300. In some cases, the workload of process 300 may be selected that is relatively simple to compile, relatively simple to execute, and/or can be run in a relatively modest amount of time (e.g., less than 10 minutes).

At 305, process 300 may include executing the workload on reference hardware and collecting hardware events. For example, design controller 140 may execute the workload on reference hardware (e.g., on a reference architecture, on a reference SoC, etc.). In some cases, design controller 140 may collect hardware events based on executing the workload on the reference hardware.

At 310, process 300 may include obtaining a figure of merit (FOM). For example, design controller 140 may obtain an FOM based on executing the workload on the reference hardware (e.g., a reference hardware FOM). In some cases, design controller 140 may select an FOM based on executing the workload on the reference hardware. Additionally, or alternatively, the workload of process 300 may be configured with a defined FOM (e.g., defined based on wall time, total wall-clock time). Wall time, also called real-world time, clock time, wall-clock time, or elapsed real time, can include the amount of time that a program or process takes to run from start to finish. In some cases, the workload may be executed on a reference architecture that has understood hardware events (e.g., well known hardware events, pre-configured hardware events). An example of a reference architecture may be the x86 architecture (e.g., x86_64 architecture).

At 315, process 300 may include performing roofline analysis to obtain an analytical model. For example, design controller 140 may performing roofline analysis based on executing the workload on the reference hardware. In some cases, design controller 140 may formulate the analytical model (e.g., analytical roofline model) based on the roofline analysis.

At 320, process 300 may include projecting performance on a target architecture based on the analytical model. For example, design controller 140 may project or estimate performance on a target architecture (e.g., target SoC architecture) based on the analytical model.

At 325, process 300 may include validating an analytical model on early hardware and/or simulator. In some cases, at 325, process 300 may include, as part of the validating the analytical model, determining whether there is a disagreement between expected performance and actual performance. In some cases, design controller 140 may execute the workload on the early hardware (e.g., hardware that is in an early stage of design, prototype hardware, etc.) and/or simulate execution of the workload on a simulator, and determine whether there is a disagreement between expected performance and actual performance. When process 300 determines there is a disagreement, then process 300 may proceed to 330. When process 300 determines there is no disagreement, then process 300 determines whether projecting the FOM on target architecture provides a satisfactory result.

At 330, process 300 may include collecting one or more additional hardware events and/or improving the analytical model. In some cases, design controller 140 may modify the analytical model based on the one or more additional hardware events, and then determine whether the modification improves the analytical model. For example, in some cases, process 300 may proceed to 320 to project performance on the target architecture based on the modified analytical model, and the analytical model may be validated at 325 to determine whether the modification improves the analytical model. Additionally, or alternatively, process 300 may return to 305 to execute the workload on the reference hardware based on the modified analytical model and/or to collect additional hardware events.

At 335, process 300 may include projecting an FOM (e.g., the FOM of 310) on the target architecture and determining whether the projecting of the FOM on the target architecture is satisfactory. For example, design controller 140 may project an FOM (e.g., the FOM of 310) on the target architecture and determine whether the FOM projected on the target architecture satisfies an expected performance of the target architecture (e.g., based on the analytical model).

At 340, process 300 may include improving one or more target architecture design points. For example, design controller 140 may improve one or more target architecture design points. In some examples, process 300 may iteratively improve one or more target architecture design points until determining the target architecture design point is satisfactory (e.g., based on returning to 335 to project the FOM on the target architecture and validating the improved design point).

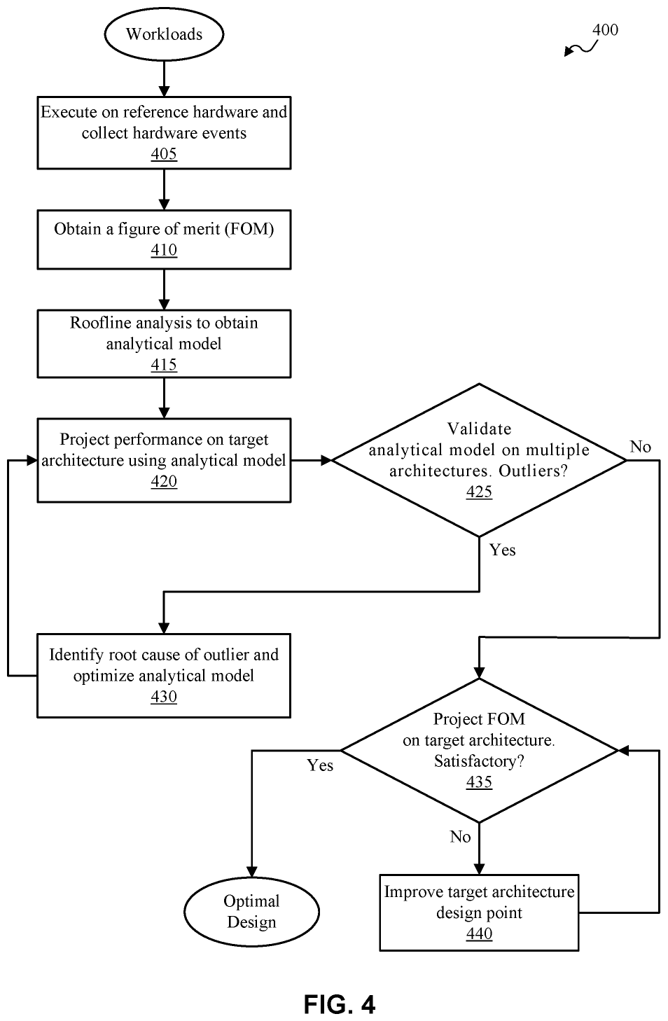

FIG. 4 illustrates an example process 400 in accordance with one or more implementations as described herein. Process 400 illustrates an example process for iterative guided architecture design based on self-optimizing analytical models. In some configurations, process 400 may be implemented by design controller 140 of FIG. 1 and/or design controller 230 of FIG. 2. In some configurations, process 400 may be implemented in conjunction with machine 105, components of machine 105, or any combination thereof. The depicted process 400 is just one implementation and one or more operations of process 400 may be rearranged, reordered, omitted, and/or otherwise modified such that other implementations are possible and contemplated.

In some examples, process 400 may initiate based on a workload (e.g., one or more workloads). In some cases, a workload that is FLOPS bound and/or memory bandwidth bound may be selected for process 400. In some cases, the workload of process 400 may be selected that is relatively simple to compile, relatively simple to execute, and/or can be run in a relatively modest amount of time (e.g., less than 10 minutes).

At 405, process 400 may include executing the workload on reference hardware and collecting hardware events. For example, design controller 140 may execute the workload on reference hardware (e.g., on a reference architecture, on a reference SoC, etc.). In some cases, design controller 140 may collect hardware events based on executing the workload on the reference hardware.

In one or more examples, a minimum number of hardware events (e.g., a minimum of three hardware events) may be measured on the reference architecture. For example, the hardware events (e.g., a minimum number of hardware events) may include (a) a total number of floating point operations; (b) a total volume of data movement between main memory and the last level of cache; and/or (c) a total hit rates on the last level of cache (LLC).

In some examples, an analytical model (e.g., of process 400) may be constructed as follows:

$$T = max ( \frac{{W}_{flop}}{α \times {R}_{flop}} , \frac{{W}_{data movement}}{β \times {R}_{main memory bandwidth}} ) \qquad Eq . 1$$

In equation 1, T may be the wall-clock time, W may represent the amount of work collected by hardware events on the reference architecture (e.g., total instruction counts), and R may represent theoretical peak rates that are known from the reference architecture specification. The values α and β may be real-valued scalar values that give the fraction of a theoretical rate that is obtained by the workload. In some cases, equation 1 represents an analytical model as described herein (e.g., an initial analytical model).

In cases where there are uncertainties in theoretical peak rates in the reference architecture, peak rates may be measured with benchmarks such as GEMM or STREAM. Hardware events may be collected by a performance analysis tool. The performance analysis tool may include an analysis tool for x86 based machines (e.g., VTune). In some cases, the amount of work, W, can be measured by hardware events collected by a performance analysis tool. The performance analysis tool could by Intel VTune on an x86-based architecture Additionally, or alternatively, the performance analysis tool could be a vendor agnostic analysis tool (e.g., open-source command line performance tool, LIKWID, etc.).

At 410, process 400 may include obtaining a figure of merit (FOM). For example, design controller 140 may obtain an FOM based on executing the workload on the reference hardware (e.g., a reference hardware FOM). In some examples, the FOM may indicate an amount of computation that a workload performs in a given time period. Thus, FOM may indicate how well a program is performing. In some cases, design controller 140 may select an FOM based on executing the workload on the reference hardware. Additionally, or alternatively, the workload of process 400 may be configured with a defined FOM (e.g., defined based on wall time, total wall-clock time). Wall time, also called real-world time, clock time, wall-clock time, or elapsed real time, can include the amount of time that a program or process takes to run from start to finish. In some cases, the workload may be executed on a reference architecture that has understood hardware events (e.g., well known hardware events, pre-configured hardware events). An example of a reference architecture may be the x86 architecture (e.g., x86_64 architecture).

At 415, process 400 may include performing roofline analysis to obtain an analytical model (e.g., equation 1). For example, design controller 140 may perform analysis (e.g., roofline analysis) based on executing the workload on the reference hardware. In some cases, design controller 140 may formulate the analytical model (e.g., analytical roofline model) based on the roofline analysis.

At 420, process 400 may include projecting performance on a target architecture based on the analytical model. For example, design controller 140 may project performance on a target architecture (e.g., target SoC architecture) based on the analytical model. In some examples, a target architecture may include an architecture design that does not yet exist, but is a target architecture configuration that a design process (e.g., process 400) is aiming to design (e.g., an optimal design). In some cases, design controller 140 may collect hardware events based on executing the workload on the reference hardware. For example, design controller 140 may collect a number of FLOPS associated with executing the workload on the reference hardware (e.g., workload FLOPS) and/or collect an amount of data movement associated with executing the workload on the reference hardware (e.g., workload data movement). In some cases, the configuration settings of the target architecture may differ from the configuration settings of the reference hardware relative to one or more aspects.

In some examples, projecting performance on the target architecture may include design controller 140 determining a level of performance (e.g., FLOPS, data movement, etc.) on the reference hardware and then projecting (e.g., estimating, mapping, modeling) the level of performance of the reference hardware onto the target architecture. For example, design controller 140 may project performance on the target architecture (e.g., estimate executing the workload on the target architecture) based on one or more differences in the configuration settings of the reference hardware relative to the configuration settings of the target architecture. In some cases, design controller 140 may determine an expected level of performance of the workload executing on the target architecture based on the projection. For example, design controller 140 may estimate a level of performance of executing the workload on the target architecture without actually running the workload on the target architecture or based on a minimized or reduced execution of the workload (e.g., executing a portion of the workload).

At 425, process 400 may include validating an analytical model on one or more architectures (e.g., one or more SoC architectures) and determining whether there are any outliers. For example, design controller 140 may validate an analytical model on one or more architectures and identify one or more outliers based on the validating. In some examples, validating the analytical model on the one or more architectures may include executing the workload on the one or more architectures (e.g., executing the workload concurrently on multiple architectures). Additionally, or alternatively, validating the analytical model on the one or more architectures may include comparing the performance of executing the workload on the one or more architectures to the analytical model. Additionally, or alternatively, validating the analytical model (e.g., equation 1) on the one or more architectures may include comparing the performance of executing the workload on at least one of the one or more architectures to the performance of executing the workload on the reference architecture (e.g., comparing a wall-clock time of at least one of the one or more architectures to a wall-clock time of executing the workload on the reference architecture). Additionally, or alternatively, validating the analytical model on the one or more architectures may include comparing the performance of executing the workload on at least one of the one or more architectures to estimating execution of the workload on the target architecture (e.g., comparing a wall-clock time of at least one of the one or more architectures to an estimated wall-clock time based on estimating execution of the workload on the target architecture).

In some examples, process 400 may include, as part of validating the analytical model, determining whether there is at least one outlier (e.g., divergence between expected performance and actual performance). For example, design controller 140 may validate an analytical model on one or more architectures based on projecting the level of performance of the reference hardware onto the target architecture, and then determining whether actual performance diverges from expected performance. In some cases, the one or more architectures may include one or more SoCs, one or more virtual machines (e.g., virtual SoCs), one or more servers, one or more computer systems, etc., or any combination thereof.

In some cases, an analytical model may be biased (e.g., inherently biased) by the reference architecture. Such an analytical model may suffice if the target architecture is based on a relatively small modification of the reference architecture. However, such an analytical model may be inadequate if the target architecture is based on a broader or disruptive architecture design space. When the target architecture is based on a broader or disruptive architecture design space, the workload may be run on an emulator or virtualized hardware (e.g., Quick Emulator (QEMU)) that supports a number of divergent architectures. For example, the workload may be run on an emulator that emulates a computer's processor through dynamic binary translation and provides a set of different hardware and device models for the machine, enabling the machine to run a variety of guest operating systems.

While some configuration settings may overlap between a first architecture and a second architecture of the one or more architectures being validated, the first architecture may include at least one configuration setting that varies with a corresponding configuration setting of the second architecture. The configuration settings of the one or more architectures can include at least one of cache structure, memory configurations, processor configurations, storage configurations, network controllers, etc. For example, the first architecture may vary from the second architecture based on at least one of cache size, cache bandwidth, cache latency, memory size, memory bandwidth, memory latency, processor clock speed, FLOPS, storage size, storage read/write speeds, or any combination thereof.

In some cases, at 425, the workloads (e.g., one or more workloads or one or more instances of a workload) are executed on various virtualized hardware and the wall-clock times may be collected (e.g., for validation). In some cases, process 400 includes ensuring that the virtualized hardware includes a divergent architecture that is distinct from the reference architecture. For example, the difference may be based on out-of-order cores vs. in-order cores, different ratios of main memory bandwidth to cache bandwidth, etc. The analytical model may be used to make a prediction for the virtualized hardware. The values W, α, and β for the reference architecture may be unchanged, while the value of R for the virtualized hardware may be used in the analytical model predictions. The projected wall-clock time may then be compared to the virtualized wall-clock time. In this data set, there are data points (e.g., virtualized vs. projected) that may disagree by some margin (e.g., differ by more than a factor of two). These data points are outliers, which may trigger additional roofline analysis. In some cases, the outliers may indicate a short-coming of the analytical model obtained by the roofline analysis on the reference architecture.

In some cases, design controller 140 may execute the workload on the one or more architectures, and determine whether there are any outliers (e.g., actual performance diverges from expected performance). In some cases, an outlier may be based on comparing an expected performance of an architecture of the one or more architectures to an actual performance of the architecture. Additionally, or alternatively, an outlier may be based on comparing an actual performance of a first architecture of the one or more architectures to an actual performance of at least one other architecture of the one or more architectures. Additionally, or alternatively, an outlier may be based on determining the actual performance of the first architecture is an outlier compared to at least the one other architecture.

When process 400 identifies an outlier (e.g., performance outlier, an aspect of actual performance that diverges from a corresponding aspect of expected performance), then process 400 may proceed to 430. When process 400 determines there are not outliers (e.g., no outliers remain after one or more iterations of process 400), then process 400 may proceed to 435. In some cases, design controller 140 may determine whether a difference between actual performance and expected performance satisfies an outlier threshold (e.g., difference between actual and expected performance is greater than the outlier threshold, difference is greater than or equal to the outlier threshold). When design controller 140 determines the difference satisfies the outlier threshold, process 400 may proceed to 430.

At 430, process 400 may include identifying a root cause of an outlier and optimizing the analytical model (e.g., analytical model derived from the roofline analysis at 415). In some cases, design controller 140 may modify the analytical model (e.g., modify equation 1) based on the outlier, and then determine whether the modification improves the analytical model. For example, in some cases, process 400 may proceed to 420 to project performance on the target architecture based on the modified analytical model (e.g., equation 2), and the analytical model may be validated at 425 to determine whether the modification improves the analytical model. In some cases, improving the analytical model may include multiple iterations of 420, 425, 430.

In some examples, parameters of the analytical model may be based on hardware events associated with the workload being executed on the reference architecture. The parameters of the analytical model may include a performance metric associated with at least one of a processor of the reference architecture, a memory of the reference architecture, or a storage device of the reference architecture based on the reference architecture executing the workload. For example, the analytical model may include at least one of a number of floating point operations based on the reference architecture executing the workload; a volume of data movement between main memory and the last level of cache based on the reference architecture executing the workload; and/or hit rates on the last level of cache (LLC) based on the reference architecture executing the workload. In some cases, modifying the analytical model may include at least one of adjusting a parameter (e.g., adjusting the number of floating point operations, adjusting a volume of data movement, adjusting a cache hit rate, etc.), adding a parameter to the analytical model (e.g., adding cache size, cache bandwidth, etc.), removing a parameter of the analytical model, adjusting a scalar value of the analytical model (e.g., adjusting α and/or β), and the like. As an example, the cache bandwidth of the first architecture of the one or more architectures may vary from an expected level of bandwidth (e.g., vary an amount that satisfies the outlier threshold), indicating an outlier. In some examples, the cache bandwidth may be incorporated into the analytical model and lead to projections that satisfy the outlier threshold for the reference architecture and all other divergent architectures that are considered in process 400.

When an outlier is identified, then process 400 may include identifying a root cause of the outlier at 430. As shown, process 400 may include optimizing an analytical model. In one or more examples, the fidelity of the analytical model may be improved by incorporating modifications (e.g., additional modifications, iterative modifications) to equation 1. In some examples, an improvement to the analytical model can be achieved by adding both FLOP and data movement terms that include a last-level cache (LLC) hit rate of the reference architecture. In some examples, the improved analytical model may be based modifications to an initial analytical model (e.g., equation 1). For instance, improving the initial analytical model may result in the following improved analytical model:

$$T = \frac{{W}_{flop}}{α \times {R}_{flop}} + \frac{{W}_{data movement}}{p \times {R}_{LLC} + ( p - 1 ) \times {R}_{main memory bandwidth}} \qquad Eq . 2$$

In equation 2, T is the wall-clock time, p is the LLC hit rate, and R_{LLC} is the bandwidth to LLC. In equation 2, p may already be obtained when the workload is executed on the reference architecture. In some cases, work data (e.g., numerators of equation 2) may be collected while executing the workload on the reference architecture. For example, work data such as number of FLOPS (e.g., W_{flop}), data movement (e.g., W_{data-movement}) may be collected based on executing the workload on the reference architecture. Based on the work data collected, performance may be predicted on a target architecture (e.g., project performance on the target architecture). In some examples, the performance may be predicted on the target architecture by plugging in work terms associated with the target architecture into the analytical model (e.g., into the corresponding numerator elements of equation 2). Additionally, or alternatively, the performance may be predicted on the target architecture by plugging in the theoretical peak rates of the target architecture into the analytical model (e.g., into the corresponding denominator elements of equation 2) and predicting performance for the target architecture (e.g., determining the wall-clock time for the target architecture). In some cases, predicting performance on the target architecture may include plugging in theoretical peak rates (e.g., R_{flop}, R_{main-memory-bandwidth}, etc.) into the target architecture.

In some examples, design controller 140 may determine whether a parameter of the one or more architectures being validated is being considered in the analytical model. For example, design controller 140 may analyze the roofline analysis and/or hardware events collected for the workload on the reference hardware to identify potential design aspects (e.g., potential root causes of the outlier) that may be missing from the analytical model. In some cases, design controller 140 may analyze a list of parameters that may be considered or included in the analytical model, identify a parameter from the list that is missing from the analytical model (e.g., potential root causes of the outlier), include the parameter in the analytical model, and re-validate the analytical model to determine whether adding the parameter improves the analytical model (e.g., removes the outlier or reduces the outlier below the outlier threshold). In some cases, the root cause of the outlier may not be on such a list. Iterations of process 400 can indicate potential root causes of the outlier based on comparing a configuration setting of the reference hardware (e.g., cache, memory, processor, storage, networking, etc.) to a corresponding configuration setting (e.g., design point) of the target configuration, and/or based on comparing a configuration setting of the reference hardware to corresponding configuration setting (e.g., design point) of at least one architecture of the one or more architectures of 425. In some examples, design controller 140 may compare a configuration setting of the reference hardware to at least one of a corresponding configuration setting of the target configuration and/or a corresponding configuration setting of at least one architecture of the one or more architectures, identify a configuration setting of the reference hardware (e.g., cache bandwidth, cache size, etc.) not represented in the analytical model based on the comparing, include the configuration setting in the analytical model, and re-validate the analytical model to determine whether adding the configuration setting improves the analytical model (e.g., removes the outlier or reduces the outlier below the outlier threshold).

In some examples, design controller 140 may compare the configurations of one or more components of the reference hardware to corresponding configurations of the target architecture and generate a list of parameters (e.g., potential root causes of the outlier) based on the one or more differences between the corresponding configurations (e.g., differences in cache bandwidth, cache size, reorder buffer size, reorder buffer bandwidth, etc.), update the analytical model to consider at least one parameter from the list of parameters, and then re-validate the updated analytical model at 425 to determine whether the update improves the analytical model (e.g., removes the outlier). Accordingly, the analytical model may be optimized based on identifying a root cause of an outlier, updating the analytical model to consider the outlier, and re-validating the analytical model.

At 435, process 400 may include projecting an FOM (e.g., the FOM of 410) on the target architecture and determining whether projecting the FOM on the target architecture is satisfactory. For example, design controller 140 may project an FOM (e.g., the FOM of 410) on the target architecture. In some examples, the target architecture may not exist for at least one iteration of process 400. Based on validation of the analytical model at 425 (e.g., based on one or more iterations of 425), a high-fidelity analytical model is generated that is capable of predicting performance on a target architecture with satisfactory confidence. In some cases, at 435, design controller 140 determines whether modifications to the analytical model (e.g., modifications made to form equation 2 based on equation 1) have resulted in the analytical model providing satisfactory results. In some cases, 435 indicates whether the FOM for the workload on the target architecture has improved. Once a high-fidelity analytical model is achieved (e.g., based on validation at 425), parameters of the target architecture (e.g., cache size, bandwidth, etc.) may be modified until FOM for the workload is improved. In some cases, one or more design points (e.g., parameters) may be adjusted. Based on the design point adjustment, design controller 140 may determine that the FOM is indifferent to the design point adjustment, indicating that the adjustment (e.g., increasing cache size) is not needed because it does not improve the FOM. In some cases, design controller 140 may determine that the FOM whether the adjustment improves the FOM (e.g., decreases wall-clock time) or worsens the FOM (e.g., increases wall-clock time), and implement design point changes accordingly to improve the FOM.

In some cases, process 400 may determine whether executing the workload on the target architecture satisfies an expected performance (e.g., based on the analytical model). In some cases, design controller 140 may determine whether a difference between actual performance on the target architecture and expected performance on the target architecture satisfies a target threshold (e.g., difference between actual and expected performance is greater than the target threshold, difference between actual and expected performance is greater than or equal to the target threshold). When design controller 140 determines the differences between actual and expected performance satisfies the target threshold, design controller 140 may indicate the projection of the FOM on the target architecture is satisfactory. In some examples, projecting the FOM on the target architecture may include executing the workload on the target architecture based on validating the analytical model (e.g., validating the analytical model on the early hardware and/or simulator). Based on an improved analytical model, process 400 may include determining whether the projection of the FOM on the target architecture satisfies an expectation of performance based on the analytical model. When projecting the FOM on target architecture does not provide a satisfactory result, then process 400 may proceed to 440. When it is determined that projecting the FOM on target architecture provides a satisfactory result, the analytical model (e.g., updated analytical model, the improved analytical model) may be implemented as an architectural design (e.g., as an optimal design). In the illustrated example, process 400 may include making an initial performance projection of the FOM for the target architecture using the analytical model (e.g., of equation 1).

At 440, process 400 may include improving one or more target architecture design points. For example, design controller 140 may improve one or more target architecture design points. In some examples, process 400 may iteratively improve one or more target architecture design points until determining the target architecture design point is satisfactory (e.g., based on returning to 435 to project the FOM on the target architecture with the improved design point). The one or more design points of the target architecture may include at least one of cache settings, memory settings, processor settings, storage settings, network settings, power settings, and the like. As one example, a design point of the target architecture may include designing the target architecture with a 4 kilobyte (KB) cache. Projecting the FOM on the target architecture may indicate that the target architecture does not satisfy a performance objective (e.g., based on a size of cache). Accordingly, improving this design point may include modifying the cache from 4 KB to 6 KB. Process 400 may then project the FOM on the target architecture with 6 KB cache and determine whether the updated target architecture satisfies an expectation of performance in line with the analytical model.

As shown, after optimizing the analytical model (e.g., based on equation 2), process 400 may return to 420 (e.g., project performance) where the optimized analytical model may be used to project performance on the target architecture. For example, process 400 may include using the optimized analytical model to project the wall-clock time using the rates of the one or more architectures (e.g., virtualized hardware). The projected and virtualized wall-clock times may then be compared. When it is determined that there are no outliers (e.g., no remaining outliers after optimization, root cause of outliers resolved), then it is determined that the analytical model (e.g., the optimized analytical model) has sufficient fidelity to be used to make design point changes on the target architecture. As shown, when there are outliers, then process 400 may include determining whether projecting the FOM on the target architecture provides a satisfactory result. When projecting the FOM on the target architecture does not provide a satisfactory result, then process 400 may include improving the target architecture design point. When it is determined that projecting the FOM on the target architecture provides a satisfactory result, then process 400 determines the analytical model (e.g., the optimized analytical model) has sufficient fidelity to be used to make design point changes on the target architecture (e.g., optimal design).

Process 400 provides multiple benefits and advantages. For example, the iterative process of process 400 provides high-fidelity analytical models and provides identification of the key hardware features of an optimal design. The identification of the key hardware features may be equivalent to identifying the most relevant degree of freedom in the target architecture design that impacts the FOM. When there are many data points to fit the analytical model, optimization algorithms may be used to fit the real-valued scalar values in the final optimized analytical model (e.g., when multiple divergent architectures are considered). Another beneficial outcome of the iterative process of process 400 is the cost savings provided based on an optimal analytical model being obtained relatively early on in the architecture design process. Additionally, the use of architecture simulators, which dilate the workload execution time by factors of hundreds or thousands, is minimized (e.g., based on one or more iterations of process 400).

In some examples, the optimized analytical model may be used to improve the design point until the projected FOM for the workload is deemed satisfactory (e.g., good enough, suitable). To fully validate the end-to-end process, an accurate architecture simulator may be used to validate the analytical model obtained through the iterative process of process 400.

Additionally, or alternatively, instead of executing the workload on virtualized hardware (e.g., of the one or more architectures of 425), the workload may be executed on real-world hardware (e.g., executed directly on real-world hardware). In addition to, or instead of, using a roofline model as an analytical model, non-roofline models may be implemented in the iterative process of process 400. For example, the analytical models of process 300 and/or process 400 may include one or more overlapping linear terms. In some examples, the use of analytical models may be fit to total instruction counts (W), instructions per cycle (α), and fraction of stalls (β). Although some analytical models may be informative, they may not directly correlate to key tunable hardware features. However, such analytical models may be incorporated in an optimization algorithm to drive the mechanism to an optimal analytical model.

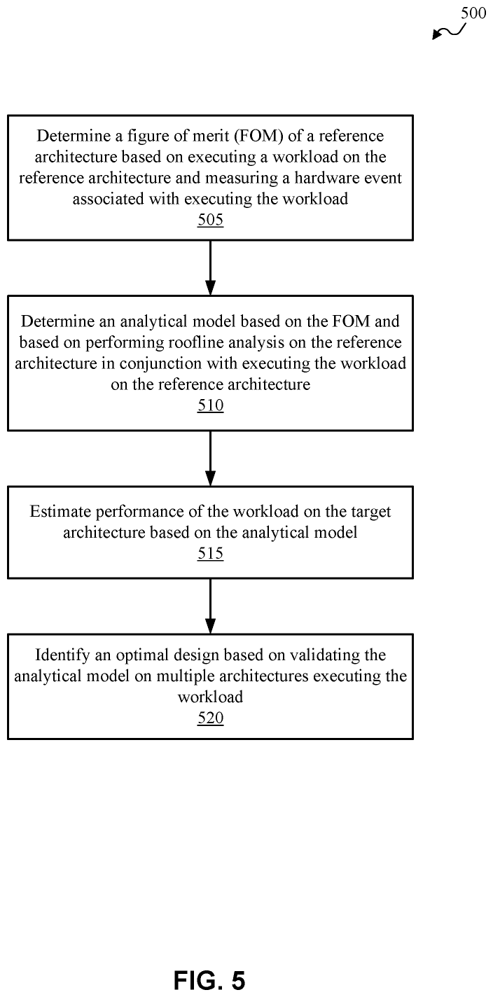

FIG. 5 depicts a flow diagram illustrating an example method 500 associated with the disclosed systems, in accordance with example implementations described herein. In some configurations, method 500 may be implemented by design controller 140 of FIG. 1 and/or design controller 230 of FIG. 2. In some configurations, method 500 may be implemented in conjunction with machine 105, components of machine 105, or any combination thereof. The depicted method 500 is just one implementation and one or more operations of method 500 may be rearranged, reordered, omitted, and/or otherwise modified such that other implementations are possible and contemplated.

At 505, method 500 may include determining a figure of merit (FOM) of a reference architecture based on executing a workload on the reference architecture and measuring a hardware event associated with executing the workload. For example, design controller 140 may determine an FOM of a reference architecture based on executing a workload on the reference architecture and measuring a hardware event associated with executing the workload.

At 510, method 500 may include determining an analytical model based on the FOM and based on performing roofline analysis on the reference architecture. For example, design controller 140 may determine an analytical model based on the FOM and based on performing roofline analysis on the reference architecture in conjunction with executing the workload on the reference architecture.

At 515, method 500 may include estimating performance of the workload on the target architecture based on the analytical model. For example, design controller 140 may estimate performance of the workload on the target architecture based on the analytical model.

At 520, method 500 may include identifying an optimal design based on validating the analytical model on multiple architectures executing the workload. For example, design controller 140 may identify an optimal design based on validating the analytical model on multiple architectures executing the workload (e.g., multiple architectures concurrently executing the workload).

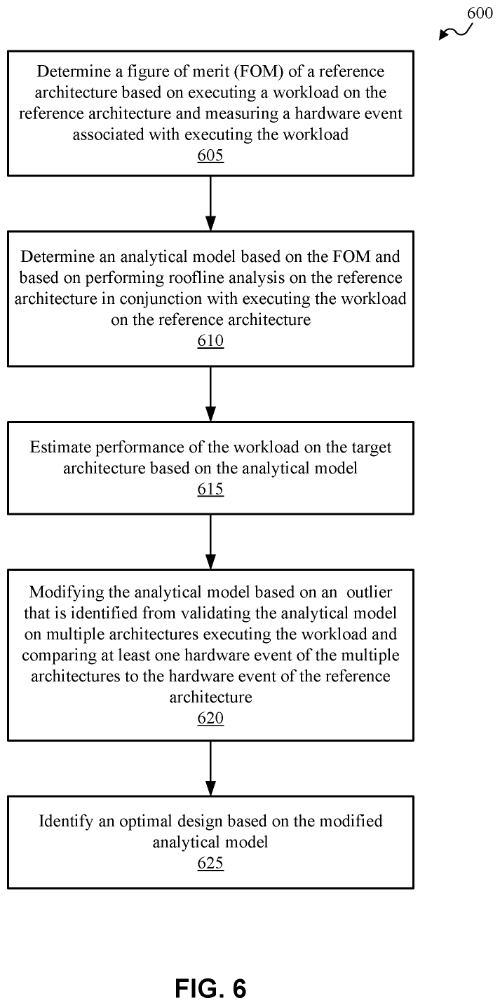

FIG. 6 depicts a flow diagram illustrating an example method 600 associated with the disclosed systems, in accordance with example implementations described herein. In some configurations, method 600 may be implemented by design controller 140 of FIG. 1 and/or design controller 230 of FIG. 2. In some configurations, method 600 may be implemented in conjunction with machine 105, components of machine 105, or any combination thereof. The depicted method 600 is just one implementation and one or more operations of method 600 may be rearranged, reordered, omitted, and/or otherwise modified such that other implementations are possible and contemplated.

At 605, method 600 may include determining a figure of merit (FOM) of a reference architecture based on executing a workload on the reference architecture and measuring a hardware event associated with executing the workload. For example, design controller 140 may determine an FOM of a reference architecture based on executing a workload on the reference architecture and measuring a hardware event associated with executing the workload.

At 610, method 600 may include determining an analytical model based on the FOM and based on performing roofline analysis on the reference architecture. For example, design controller 140 may determine an analytical model based on the FOM and based on performing roofline analysis on the reference architecture in conjunction with executing the workload on the reference architecture.

At 615, method 600 may include estimating performance of the workload on the target architecture based on the analytical model. For example, design controller 140 may estimate performance of the workload on the target architecture based on the analytical model.

At 620, method 600 may include modifying the analytical model based on an outlier that is identified from validating the analytical model on multiple architectures executing the workload and comparing at least one hardware event of the multiple architectures to the hardware event of the reference architecture. For example, design controller 140 may identify an outlier based on validating the analytical model on the multiple architectures executing the workload and comparing at least one hardware event of the multiple architectures to the hardware event of the reference architecture. In some cases, design controller 140 may modify the analytical model based on the identified outlier.

At 625, method 600 may include identify an optimal design based on the modified analytical model. For example, design controller 140 may identify an optimal design based on the analytical model being modified in response to the outlier that is identified based on validating the analytical model.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as ‘communicating’, when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some embodiments may be used in conjunction with one or more types of wireless communication signals and/or systems following one or more wireless communication protocols, for example, Radio Frequency (RF), Infrared (IR), Frequency-Division Multiplexing (FDM), Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth™, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other embodiments may be used in various other devices, systems, and/or networks.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example an FPGA (field programmable gate array) or an ASIC (application-specific integrated circuit). The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example a CRT (cathode ray tube) or LCD (liquid crystal display) monitor, for displaying information/data to the user and a keyboard and a pointing device, for example a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example as an information/data server, or that includes a middleware component, for example an application server, or that includes a front-end component, for example a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples described herein set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A method of optimizing an architecture design, the method comprising:
determining a figure of merit (FOM) of a reference architecture based on executing a workload on the reference architecture and measuring a hardware event associated with executing the workload, the hardware event comprising a performance metric associated with at least one of a processor of the reference architecture, a memory of the reference architecture, or a storage device of the reference architecture;
determining an analytical model based on the FOM and based on performing roofline analysis on the reference architecture;
estimating performance of the workload on a target architecture based on the analytical model; and
identifying an optimal design of the target architecture based on validating the analytical model on a plurality of architectures executing the workload.

2. The method of claim 1, further comprising identifying an outlier based on validating the analytical model, wherein validating the analytical model is based on the plurality of architectures executing the workload and comparing at least one hardware event of the plurality of architectures to the hardware event of the reference architecture.

3. The method of claim 2, further comprising:
determining a root cause of the outlier that is identified based on validating the analytical model on the plurality of architectures, wherein the root cause of the outlier is determined based on at least one of:
analyzing a list of parameters and determining a parameter from the list of parameters is not represented in the analytical model,
comparing a configuration setting of the reference hardware to at least one of a corresponding configuration setting of the target configuration or a corresponding configuration setting of at least one architecture of the plurality of architectures, and identifying a configuration setting of the reference hardware not represented in the analytical model based on the comparing; and
modifying the analytical model based on the outlier, wherein modifying the analytical model includes at least one of:
adjusting a parameter of the analytical model,
adding a parameter to the analytical model,
removing a parameter of the analytical model,
adjusting a scalar value of the analytical model.

4. The method of claim 3, further comprising determining the outlier is resolved based on validating the modified analytical model on the plurality of architectures, wherein the modified analytical model.

5. The method of claim 3, further comprising identifying a design point deficiency in the target architecture based on estimating performance of the workload on the target architecture using the modified analytical model.

6. The method of claim 5, further comprising modifying the target architecture based on modifying a design point of the target architecture to resolve the design point deficiency.

7. The method of claim 5, wherein identifying the optimal design is based on estimating performance of the workload on the modified target architecture using the modified analytical model.

8. The method of claim 1, further comprising wherein the FOM comprises at least a wall-clock time associated with the workload executing on the reference architecture.

9. The method of claim 1, wherein:
the plurality of architectures includes a first virtual machine and a second virtual machine,
a first configuration setting of an architecture of the first virtual machine diverges from a corresponding configuration setting of the reference architecture and the second virtual machine, and
a second configuration setting of an architecture of the second virtual machine diverges from a corresponding configuration setting of the reference architecture and the first virtual machine.

10. The method of claim 9, wherein:
the reference architecture comprises a system-on-chip (SoC) architecture,
the first virtual machine comprises a first virtual SoC architecture, and
the second virtual machine comprises a second virtual SoC architecture.

11. A device, comprising:
at least one memory; and
at least one processor coupled with the at least one memory configured to:
determine a figure of merit (FOM) of a reference architecture based on executing a workload on the reference architecture and measuring a hardware event associated with executing the workload, the hardware event comprising a performance metric associated with at least one of a processor of the reference architecture, a memory of the reference architecture, or a storage device of the reference architecture;
determine an analytical model based on the FOM and based on performing roofline analysis on the reference architecture;
estimate performance of the workload on a target architecture based on the analytical model; and
identify an optimal design of the target architecture based on validating the analytical model on a plurality of architectures executing the workload.

12. The device of claim 11, wherein the at least one processor is configured to identify an outlier based on validating the analytical model, wherein validating the analytical model is based on the plurality of architectures executing the workload and comparing at least one hardware event of the plurality of architectures to the hardware event of the reference architecture.

13. The device of claim 12, wherein the at least one processor is configured to:
determine a root cause of the outlier that is identified based on validating the analytical model on the plurality of architectures, wherein the root cause of the outlier is determined based on at least one of:
analyzing a list of parameters and determining a parameter from the list of parameters is not represented in the analytical model,
comparing a configuration setting of the reference hardware to at least one of a corresponding configuration setting of the target configuration or a corresponding configuration setting of at least one architecture of the plurality of architectures, and identifying a configuration setting of the reference hardware not represented in the analytical model based on the comparing; and
modify the analytical model based on the outlier.

14. The device of claim 13, wherein the at least one processor is configured to determine the outlier is resolved based on validating the modified analytical model on the plurality of architectures.

15. The device of claim 13, wherein the at least one processor is configured to identify a design point deficiency in the target architecture based on estimating performance of the workload on the target architecture using the modified analytical model.

16. The device of claim 15, wherein the at least one processor is configured to modify the target architecture based on modifying a design point of the target architecture to resolve the design point deficiency.

17. The device of claim 15, wherein identifying the optimal design is based on estimating performance of the workload on the modified target architecture using the modified analytical model.

18. A non-transitory computer-readable medium storing code that comprises instructions executable by a processor of a device to:
determine a figure of merit (FOM) of a reference architecture based on executing a workload on the reference architecture and measuring a hardware event associated with executing the workload, the hardware event comprising a performance metric associated with at least one of a processor of the reference architecture, a memory of the reference architecture, or a storage device of the reference architecture;
determine an analytical model based on the FOM and based on performing roofline analysis on the reference architecture;
estimate performance of the workload on a target architecture based on the analytical model; and
identify an optimal design of the target architecture based on validating the analytical model on a plurality of architectures executing the workload.

19. The non-transitory computer-readable medium of claim 18, wherein the code includes further instructions executable by the processor to cause the device to identify an outlier based on validating the analytical model, wherein validating the analytical model is based on the plurality of architectures executing the workload and comparing at least one hardware event of the plurality of architectures to the hardware event of the reference architecture.

20. The non-transitory computer-readable medium of claim 19, wherein the code includes further instructions executable by the processor to cause the device to:
determine a root cause of the outlier that is identified based on validating the analytical model on the plurality of architectures, wherein the root cause of the outlier is determined based on at least one of:
analyzing a list of parameters and determining a parameter from the list of parameters is not represented in the analytical model,
comparing a configuration setting of the reference hardware to at least one of a corresponding configuration setting of the target configuration or a corresponding configuration setting of at least one architecture of the plurality of architectures, and identifying a configuration setting of the reference hardware not represented in the analytical model based on the comparing; and
modify the analytical model based on the outlier.
